(19) United States
(12) Patent Application Publication
(10) Pub. No.: US 2010/0139772 A1
(43) Pub. Date: Jun. 10, 2010

(54) NANOWIRE SENSITIZED SOLAR CELLS

(75) Inventors: Arthur J. Frank, Lakewood, CO (US); Nathan R. Neale, Denver, CO (US); Kai Zhu, Littleton, CO (US)

Correspondence Address: PAUL J WHITE, PATENT COUNSEL;NATIONAL RENEWABLE ENERGY LABORATORY (NREL), 1617 COLE BOULEVARD, MS 1734, GOLDEN, CO, 80401-3393, US

(73) Assignee: Alliance for Sustainable Energy, LLC, Golden, CA (US)

(21) Appl. No.: 12/616,363

(22) Filed: Nov. 11, 2009

Related U.S. Application Data
(60) Provisional application No. 61/113,476, filed on Nov. 11, 2008.

(51) Int. Cl. H01L 31/00; H01L 31/18; H01L 21/04; H01L 31/0352

(52) U.S. Cl. 136/261; 438/63; 438/478; 257/21; 136/252; 977/762; 257/14; 257/E21.04; 257/E31.032

(57) ABSTRACT

An inorganic two-phase nanowire structure including an inorganic semiconducting nanoporous charge conducting phase, and, an inorganic semiconductor nanowire array disposed within at least one of the pores of the nanoporous charge conducting phase.

### CROSS REFERENCE TO RELATED APPLICATIONS

The present application claims priority from U.S. Provisional Patent Application No. 61/113,476, filed 11 Nov. 2008; the subject matter of which hereby is specifically incorporated herein by reference for all that it discloses and teaches.

### CONTRACTUAL ORIGIN

The United States Government has rights in this invention under Contract No. DE-AC36-08GO28308 between the United States Department of Energy and the National Renewable Energy Laboratory, managed and operated by the Alliance for Sustainable Energy, LLC.

### BACKGROUND

Nano-scale materials of many types are being developed and used for a variety of purposes. Nano-scale materials such as nanowires, also referred to as NWs herein, or nanotubes, also referred to herein as NTs, have been produced having relatively small diameters (e.g., on the order of nano-meters), and having much longer lengths relative to such diameters; these characteristics providing many of these nano-scale wires with unique properties that can make them promising candidates for a wide range of applications.

Though such nano-scale nanowires or nanotubes have been known and used in a variety of applications, alternatives are yet being sought. Even so, the descriptions of related art herein and any potential limitations related therewith are intended to be illustrative and not exclusive. Other limitations of the related art will become apparent to those of skill in the art upon a reading of the present specification and a study of the drawings.

### SUMMARY

The following implementations and aspects thereof are described and illustrated in conjunction with systems, apparatuses, compositions and methods which are meant to be exemplary and illustrative, not limiting in scope. A general aspect of the presently described developments may include providing an inorganic two-phase nanowire structure with at least one ordered phase, including an inorganic semiconducting nanoporous charge conducting phase, and an inorganic semiconductor nanowire array interpenetrated within the nanoporous charge conducting phase. Non-limiting examples include a sensitized solar cell incorporating an inorganic two-phase nanowire structure.

Another aspect may include methods for producing and/or using an inorganic two-phase nanowire structure including an inorganic nanoporous charge conducting phase and an inorganic nanowire array disposed within at least one of the pores of the nanoporous charge conducting phase.

The foregoing specific aspects and advantages of the present developments are illustrative of those which can be achieved by these developments and are not intended to be exhaustive or limiting of the possible advantages which can be realized. Thus, those and other aspects and advantages of these developments will be apparent from the description herein or can be learned from practicing the disclosure, both as embodied herein or as modified in view of any variations which may be apparent to those skilled in the art. Thus, in addition to the exemplary aspects and implementations described above, further aspects and implementations will become apparent by reference to the drawings and by study of the following descriptions.

### BRIEF DESCRIPTION OF DRAWINGS

Exemplary implementations are illustrated in referenced figures of the drawings. It is intended that the implementations and figures disclosed herein are to be considered illustrative rather than limiting. In the drawings:

FIG. 1 provides a schematic view of a nanowire structures, particularly of an ordered network illustrating one or more of the exemplary embodiments;

FIG. 2, which includes sub-part FIGS. 2A, 2B and 2C provides alternative conventional solar cell structures;

FIG. 3 is another alternative conventional solar cell structure;

FIG. 4, which includes sub-part 4A and 4B, provides further alternative conventional solar cell structures, FIG. 4B being a cross-sectional view of FIG. 4A;

FIG. 5 is flow chart of an exemplary method; the first two operations not necessarily in this order;

FIG. 6, which includes sub-parts 6(a), 6(b), 6(c) and 6(d), provides X-ray diffraction (XRD) characterizations of examples;

FIG. 7, which includes sub-parts 7(a) and 7(b), provides schematic views of alternative deposition results;

FIG. 8 provides simulation curves for ambipolar diffusion coefficients (solid lines) and effective electron diffusion lengths (dashed lines);

FIG. 9, which includes sub-parts 9(a), 9(b) and 9(c), provides current profiles of pulse electrodeposition of CIS into TiO₂ nanotube electrodes;

FIG. 10, which includes sub-parts 10(a) and 10(b), provides scanning electron microscopy (SEM) images of examples;

FIG. 11, which includes sub-parts 11(a), 11(b) and 11(c), provides still further scanning electron microscopy (SEM) images of still further examples;

FIG. 12, which includes sub-parts 12(a), 12(b), 12(c) and 12(d), provides chemical capacitance vs. potential plots of mesoscopic TiO₂ films in different electrolytes;

FIG. 13 provides a current v. voltage plot of photoelectric effect of representative materials; and,

FIG. 14, which includes sub-part 14A and 14B, provides a SEM image of a nanowire mesh.

### DETAILED DESCRIPTION

Presented here are systems, apparatuses, products, compositions and/or methods of manufacture and/or use which involve nanowires formed or otherwise disposed in one or more composite products which can be used as or in solar cells presenting good electrical generation characteristics. More particularly in some implementations, provided here are non-organic semiconductor nanowires (NWs) which may be disposed to fill one or more empty pores or pore spaces of a semiconducting nanoporous inorganic material (e.g., a metal oxide, inter alia), and processes for the fabrication and/or use. These may be oriented or non-oriented, quantum and/or non-quantum nanowire products and in many cases are disposed as nanowire sensitized solar cells. Exemplary nanowire products and methods of production and use may be better understood with reference to the Figures and the following description though it should be understood that various alternative nanowire products and production methods may be used.

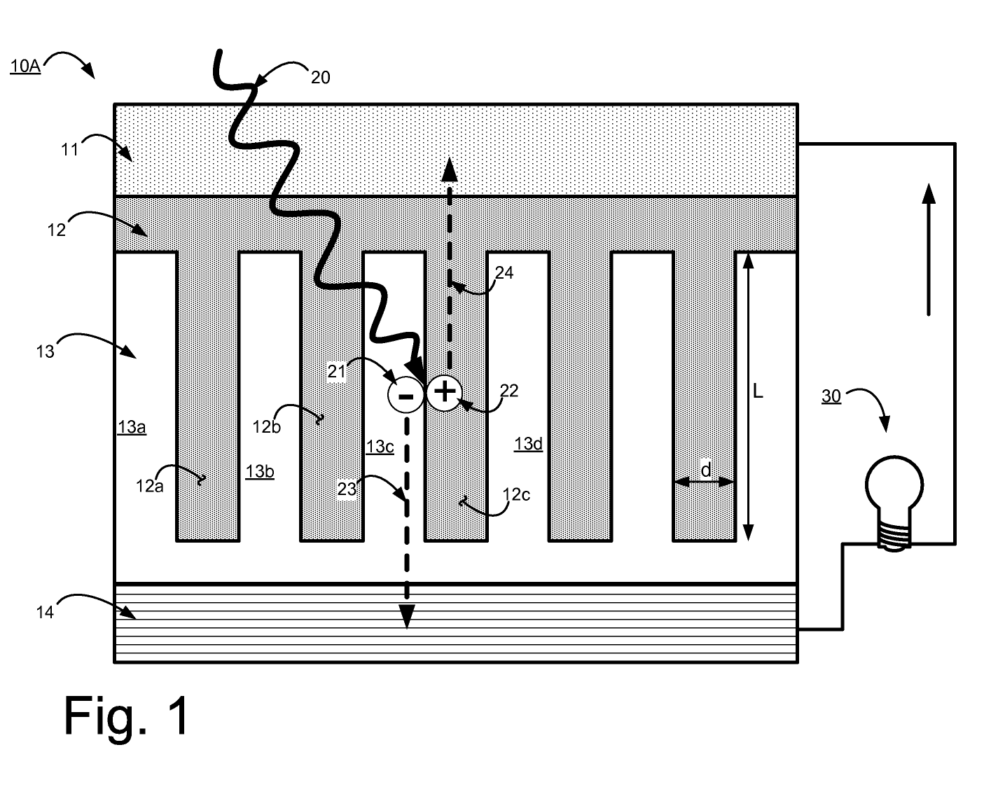

More particularly, illustrated in some implementations here are new types of architectures for sensitized nanocrystalline solar cells, also referred to here as sensitized solar cell (SSC) structures in which either an oriented array or an ordered, but nonoriented, network of quantum and/or non-quantum inorganic p-type semiconductor nanowires (NWs) are formed within or disposed to fill the spaces and/or empty pores of a typically thin layer of a relatively wider bandgap semiconducting nanoporous inorganic material (e.g., metal oxide such as TiO₂, etc.). The ordered pore structure of the relatively wider bandgap semiconductor may serve as a template to control the diameter, length, shape, orientation, and density of the nanowires (NWs). The semiconductor nanowires may serve as both a sensitizer (light absorber and source of photoinjected charges (electrons or holes)) and hole (or electron) conductor and the relatively wider bandgap semiconductor may serve as the electron (or hole) conductor. More detailed explanations and variations are provided below (see e.g., FIG. 1, described in detail below). Alternatively, a semiconductor nanowire array may serve as a template to control the shape, orientation and density of a second semiconductor array. In either case, one or both semiconductor phases may serve as the light harvesting phases but may then also be charge conducting. Such a device structure has the potential for ultrahigh solar conversion efficiencies (up to about 66%).

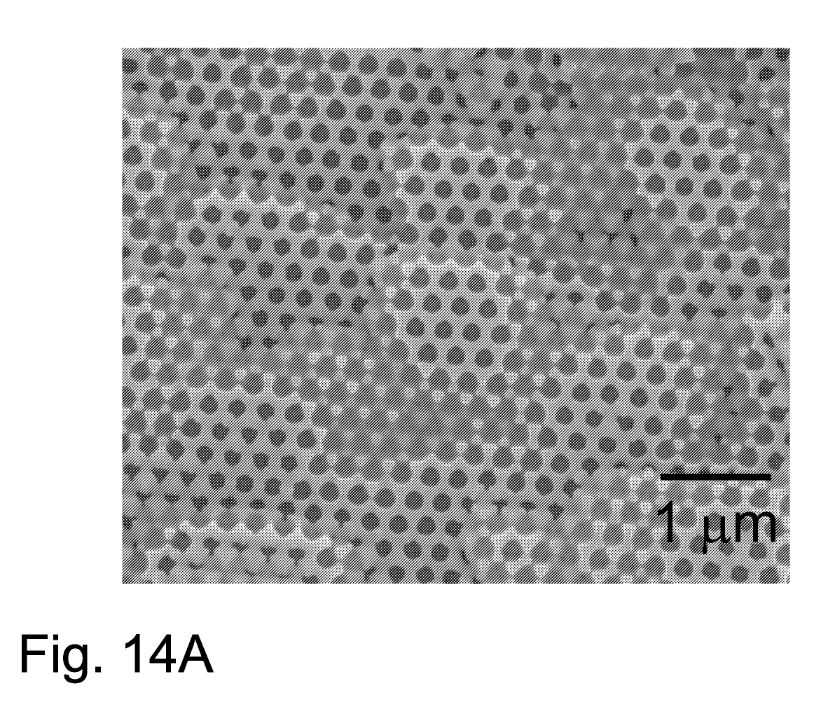

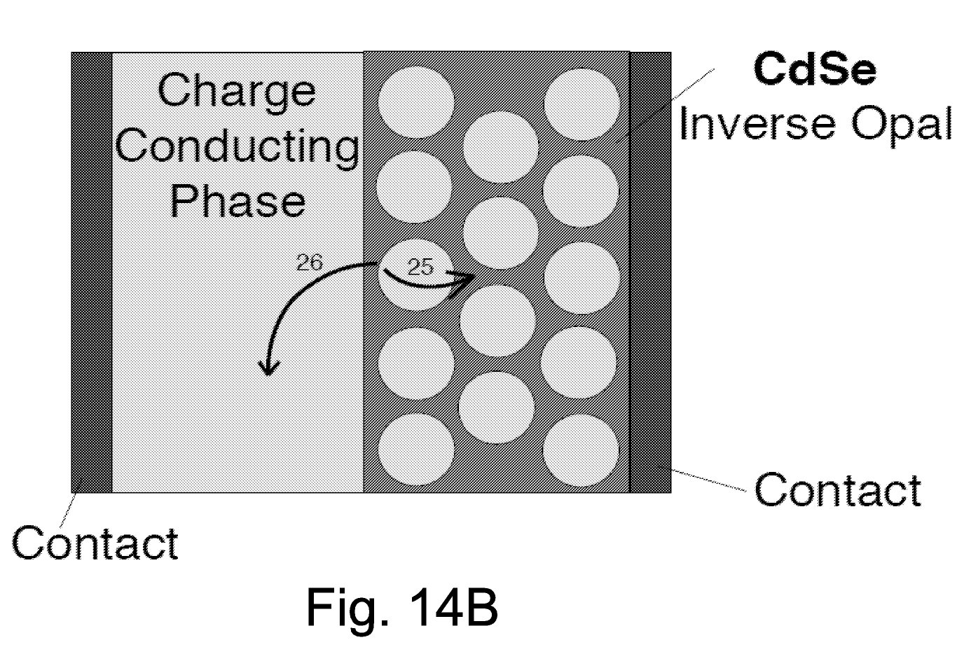

As such, the present developments may be appreciated as a conceptual variation of quantum-dot (QD) sensitized solar cells, which notably implements a third phase to serve as a charge conductor, and achieve very high efficiency at low cost. More particularly, a resulting oriented array or non-oriented network of a p-type semiconductor (not shown in FIG. 1, but see FIG. 14 described below) nanowire sensitized solar cell may present similar unique potential capabilities like those of a quantum dot (QD) sensitized, i.e., QD-sensitized, solar cell to reach high thermodynamic conversion efficiencies of perhaps up to about 66% by utilizing hot photo-generated carriers or by producing high photo-current to produce very high photocurrents via multiple electron-hole pair (exciton) generation created by the absorption of a single high-energy photon. In an exemplary cell structure, quantum (and/or non-quantum) nanowires replace physically and functionally both the quantum dot sensitizers and the hole conductors. The potential advantage of such a nanowire structure over quantum dots may typically be more efficient hole (or electron) transport.

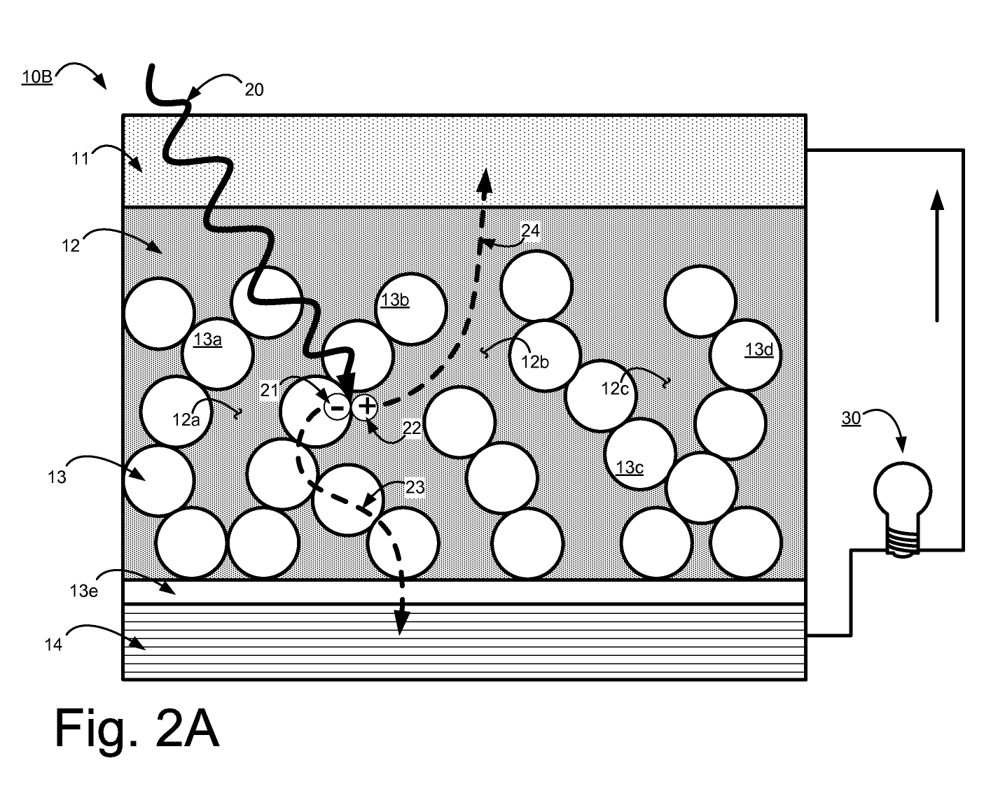

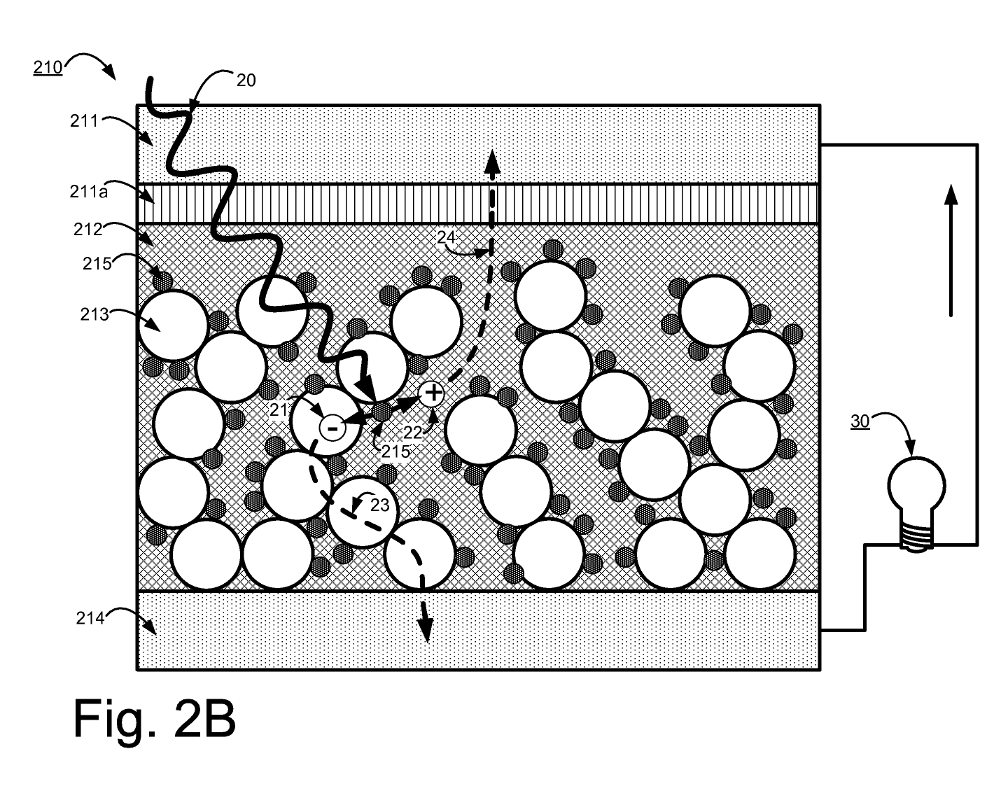

Referring now more particularly to FIG. 1; shown is a generalized depiction, i.e., a schematic of cell structure 10A, with, in FIG. 1, a network which includes ordered and/or oriented (oriented is shown in FIG. 1, non-oriented not here, but see description of FIG. 14, below) p-type semiconductor (p-SC) nanowires 12 (see particularly, the respective exemplary interstitial wires 12(a), 12(b) and 12(c); these being disposed/formed between the respective pore walls 13(a), 13(b), 13(c) and 13(d), for example). This ordered disposition is contrasted with the example 10B of FIG. 2A, a disordered network of p-SC nanowires 12 (nanowires used in a non-strictly non-ordered, non-oriented or non-uniform sense in FIG. 2A; see here also in particular, the respective exemplary interstitial wire structures 12(a), 12(b) and 12(c) between the respective pore wall structures 13(a), 13(b), 13(c) and 13(d) (represented here schematically, and without limitation thereto, by the circular structures connected one to another)). In between the orientationally ordered exemplary subject of FIG. 1 and the disordered conventional cell structure of FIG. 2A is a non-orientationally ordered network such as the inverse opal shown in FIG. 14, see further details below. Whether merely ordered or orientationally ordered, each of the examples are formed within the otherwise empty pore space of thin layers of a nanoporous charge conducting phase 13, for example, about 1-2 μm (microns) of a nanoporous metal oxide, for example, titanium oxide (TiO₂). The pore structure of the nanoporous charge conducting phase 13 may serve as a template for disposition of the nanowires. The nanowire diameter, d (see e.g., FIG. 1), may vary from about 1 to about 15 nm or even up to perhaps 50 nm (for some materials) for quantum nanowires and from about 2 or greater than 2 nm for non-quantum wires; noting that all quantized or non-quantized determinations are material specific for different sizes of nanowire structures. A very thin wire (e.g., 1 nm) may be self-supporting (such that it does not bend, fall or collapse), though such may be more structurally sound if part of a matrix, as for example a support matrix.

Still more particularly, as shown in FIG. 1, the cell structure 10A includes a first contact 11, here, e.g., a TCO (or transparent conducting oxide such as tin oxide (SnO₂)) contact 11, and a second contact 14, here, e.g., a titanium or Ti contact 14 (although many different materials may be used for either of the contacts; noting that it may be that either or both contacts may be transparent), between which are positioned the nanoporous charge conducting phase 13, here a metal oxide, e.g., TiO₂, structure 13, the nanoporous charge conducting phase or structure 13 forming an ordered and oriented array of pores for disposition of the nanowire array 12 therewithin. As introduced above, the conventional FIG. 2A shows a similar arrangement/cell structure 10B, where, however, between the TCO contact 11 and a Ti contact 14, the nanoporous charge conducting phase, here metal oxide, TiO₂, forms a disordered network of pores for disposition of the nanowire type structures 12 therewithin (note, the ordered layer 13e of TiO₂ in FIG. 2A, upon which the nanoporous charge conducting phase was here disposed or formed). When excited by light (see energy or light wave 20), p-SC nanowire phase 12 generates electron-hole pairs, which separate into electrons and holes (see electron 21 and hole 22) upon reaching the p-SC/TiO₂ interfaces. Electrons are injected into the TiO₂ which then transmit them to the collecting Ti contact; see electron path 23. The nanowires 12 transmit the resulting holes to the collecting TCO contact; see hole path 24. More particularly, in both cases (i.e., in both FIGS. 1 and 2A), the light energy is schematically represented at 20 (hv), which impacts the p-SC/TiO₂ interfaces and generates the electron hole pair, electron 21 and hole 22. The electron then follows the charge conducting path 23 through the nanoporous charge conducting medium or phase 13 and the hole follows the hole conducting path 24 through the hole conducting medium, here nanowires 12 to the respective collectors 14 and 11 to then create an electrical circuit shown schematically at 30 (the electrons flowing upwardly in this external circuit 30). It may be noted however, that the ordered systems may provide unanticipated operational improvements; conduction is expected to be improved with fewer losses of charges owing to recombination. It is noted that the exact mechanism of the charge-collection improvement afforded by the ordered/oriented NW architecture is not limiting.

Thus provided as shown in FIG. 1 (and FIG. 14, see below) is, in many an implementation, an inorganic two-phase nanowire sensitized solar cell. As such, this configuration is a two-phase system in which an inorganic material acts as the sensitizer (light absorber and source of photoinjected electrons or holes) and hole (or electron)-conducting phase. The electron (or hole)-conducting phase 13 may often be a wide-bandgap (although either phase may have the wider bandgap so long as the two may generally not have substantially the same bandgap) metal oxide or other charge-conducting material capable of electron (or hole) conduction and transparent or semitransparent to wavelengths of light absorbed by the sensitizer. An ordered pore system (2D oriented as in FIG. 1 or a 3D non-orientationally ordered system as in FIG. 14, et al.) of this phase 13 can act as a template for the inorganic semiconducting nanowire material 12 resulting in a corresponding ordered inorganic nanowire array 12 or disordered inorganic network 12. The combined hole-conducting phase and sensitizer, represented as an array or a network 12 in FIG. 1, e.g., may often be an inorganic nanowire semiconductor which serves as a sensitizer (light absorber and source of photoinjected charge (electrons or holes) and hole (or electron) conductor. As introduced above, the nanowires 12 may be quantized or non-quantized. Generally, an oriented nanowire array in an ordered linear (or often also in a nonordered, non-linear) pore system can provide a 1-D pathway (or a very narrow, limited 2-D or even a 3-D pathway) for conduction.

Although the example shown in FIG. 1 depicts the cross section of an orientationally ordered (FIG. 1), porous TiO₂ network with substantially 1-D pores (linear in FIG. 1, non-orientational/non-linear in FIG. 14) as the electron-conducting phase, other configurations (e.g., ordered, porous TiO₂ networks with 2-D or 3-D channels creating nanowire meshes, ordered nanotube arrays creating nanowires with inner pores as liner channels, etc.) and materials (e.g., ZnO, SnO₂, etc.) are possible and fall under this category. Also, whereas FIG. 1 and the phase descriptions indicate n-type metal oxides and p-type inorganic semiconductors, the reverse configuration is possible, as well, wherein transparent or semi-transparent p-type inorganic materials (e.g., CuSCN, CuI, GaN, NiO, Si, etc.) and n-type inorganic nanowire semiconductor sensitizers (e.g., CdSe, Si, etc.) can be used to make up the nanowire sensitized solar cell. A third configuration which is an extension is an arrangement in which both the n- and p-type phases, one of which being a nanowire array or network, are light absorbers. Yet another variation included here is that the template used to prepare the inorganic semiconductor nanowire array may not be incorporated into the final device. For instance, a membrane (e.g., an anodized aluminum oxide (AAO), MCM-41 (mobile catalytic material number 41), SBA-15, etc.) having ordered pores 1-500 nm in diameter may be used as the template and then removed after the nanowire array is fabricated within its pores. Alternatively, inorganic semiconducting nanowire arrays may be grown without a template. In either case, the interstitial space between the nanowires may be filled with an appropriate charge-conducting phase (e.g., TiO₂, CuSCN, etc.) depending on the minority charge carrier (n or p) type of the inorganic nanowire semiconductor.

Note further these examples are only schematically shown in and described with relation to the substantially complete pore-filling as may be represented by FIG. 1; a great many potential alternative implementations not constricted by the physical forms of FIG. 1 may incorporate one or more features regardless of size, scale, shape, or manner of operation. Structures need not be any particular shape, but may take many shapes depending upon end use.

Thus provided is a new type of architecture (see particularly FIG. 1) for sensitized nanocrystalline solar cells which may achieve very high efficiency at low cost. An oriented array or non-oriented network of p-type semiconductor nanowires quantum and or non-quantum nanowires fills the empty pore space of a thin layer of a nanoporous wide-bandgap semiconducting material, for example, but not limited to, a metal oxide, such as TiO₂. The pore structure of TiO₂ can thus serve as a template to control the diameter, length, shape, orientation, and density of the nanowires. A nanowire-sensitized solar cell may have the same or similar unique potential capabilities of quantum dot QD-sensitized solar cell to reach thermodynamic conversion efficiencies of up to about 66% by utilizing hot photogenerated carriers to produce very high photocurrents via multiple electron-hole pair, i.e., exciton, generation created by the absorption of a single high-energy photon. The new solar cell architecture surmounts a technological impediment that limits efficient charge transport in QD cells namely, the necessity to combine QDs with a hole conductor to transport photogenerated charges from the individual QDs to the charge collecting contact. In the present cell structure, nanowires replace physically and functionally both the QD sensitizers and hole conductor. Organizing the nanowires as an oriented array can improve the electron and hole transport properties and reduce recombination losses. As mentioned, the new type of architecture for sensitized nanocrystalline solar cells may involve either or both quantum or non-quantum, narrow or wide-bandgap, p-type semiconducting nanowire sensitizers (noting generally that the p-type and n-type materials can not have substantially the same bandgap as each other). Narrow-bandgap p-type semiconductors, for example, but not limited to; Copper Oxide, CuO (1.35 eV); Cadmium Telluride, CdTe (1.56 eV), and Cadmium Selenide, CdSe (1.7 eV), have the potential to achieve much higher light-harvesting efficiencies than current state-of-the-art dyes used in the most efficient dye-sensitized solar cells.

By way of structural comparison, the structures may be compared directly with others; e.g., substantially conventional alternatives. A first example was FIG. 2A, as set forth above. For a second example, FIG. 2B presents a detailed schematic of a conventional three-phase dye sensitized solar cell 210 with a number of pores defined by a nanoporous structure or network 213 filled by a hole conducting phase 212 and a sensitizer, here quantum dots 215. Thus, it includes three distinct phases: (a) an electron-conducting phase 213, (b) a hole-conducting phase 212, and (c) a sensitizer (light absorber and source of photoinjected charges—electrons or holes) 215. Although the example shown in FIG. 2B depicts the electron-conducting phase as a disordered, porous, nanocrystalline TiO₂ network, other configurations (e.g., ordered nanowire arrays, mixed nanowires and nanoparticles, etc.) and materials (e.g., ZnO, SnO₂, etc.) are possible. Charge separation occurs at the interface of the electron- and hole-conducting phases. More particularly, the electron-conducting phase may include a wide-bandgap semiconductor (e.g., metal oxide) capable of electron conduction and transparent or semitransparent to wavelengths of light absorbed by the sensitizer. The hole-conducting phase may include a liquid (e.g., acetonitrile, ionic liquid, etc.), gel (e.g., ionic liquid in PVDF-HFP matrix (polyvinylidene), etc.) or solid-state (e.g., CuSCN, CuI, etc.) electrolyte capable of reducing oxidized species (i.e. accepting holes from dye molecules) and transporting holes to the hole-collecting substrate. And, the sensitizer may include an organic, coordination complex or inorganic (e.g., quantum dot (QDs), etc.) chromophore, which serve as light absorber and source of photoinjected electrons, and is located at the interface of the electron- and hole-conducting phases. Thus, the QD sensitizers 215 generate the electron 21 and hole 22 upon interaction with the light wave 20. Also shown are the two TCO contacts 211 and 214 and a catalyst layer 211a. Such a three-phase system is in contrast with the two phase system of FIG. 1.

As such, the present developments as shown in FIG. 1 may be appreciated as a discrete variation of quantum-dot sensitized solar cells as shown in FIG. 2B, e.g., to achieve very high efficiency at low cost. More particularly, a resulting oriented array or non-oriented network of a p-type semiconductor nanowire sensitized solar cell may have similar unique potential capabilities like those of a quantum dot (QD) sensitized, i.e., QD-sensitized, solar cell to reach high thermodynamic conversion efficiencies by utilizing hot photo-generated carriers or by producing very high photocurrents via multiple electron-hole pair (exciton) generation created by the absorption of a single high-energy photon. In addition, the new solar cell architecture may surmount a technological impediment that limits efficient charge transport in quantum dot cells; namely, the present inability to prepare quantum dots in sufficiently close proximity to form minibands. A consequence of this issue is the necessity to combine quantum dots with a hole conductor to transport photogenerated charges from the individual quantum dots to the charge collecting contact. In the cell structure of FIG. 1, quantum (and non-quantum) nanowires replace physically and functionally both the quantum dot sensitizers and hole conductor. A potential advantage of nanowires over quantum dots can be more efficient hole transport. Furthermore, organizing the nanowires as an oriented array may improve the electron and hole transport properties and reduce recombination losses. These developments also pertain to a related cell architecture, involving nonquantum, narrow or wide-bandgap p-type semiconducting nanowire sensitizers. Several narrow-bandgap p-type semiconductors (for example, but not limited to, CuO (1.35 eV), CdTe (1.56 eV), and CdSe (1.7 eV)) have the potential to achieve much higher light-harvesting efficiencies than current state-of-the-art dyes used in the most efficient dye-sensitized (e.g., quantum dot) solar cells.

FIG. 2C provides another alternative schematic from the state of the art, here involving an organic-inorganic hybrid two-phase sensitized solar cell 310. As a two-phase system, in this configuration it is the organic material 312 which acts as the sensitizer (light absorber and source of photoinjected electrons) and hole-conducting phase. Although the example shown in FIG. 2C depicts the electron-conducting phase 313 as a disordered, porous, nanocrystalline TiO₂ network, other configurations (e.g., ordered nanowire arrays) and materials (e.g., ZnO, SnO₂, etc.) are possible and fall under this category. Here, the electron-conducting phase 313 may include a wide bandgap metal oxide material capable of electron conduction and may be transparent or semitransparent to wavelengths of light absorbed by the sensitizer. The hole-conducting and sensitizer phase 312 is an organic material, typically a semiconducting polymer, in which hole conduction occurs in the organic polymer's delocalized pi-system. Note, because the polymer molecular backbone is disordered, hole transport is not spatially confined to one dimension, even if the macroscopic polymer phase were ordered, for example, filling of the pores of an ordered, oriented TiO₂ NT array. The sensitizer within the hole-conducting and sensitizer phase 312 forms the electron 21 and hole 22 upon interaction with the light wave 20. Also shown are the respective TCO and Ti contacts 311 and 314 and a TiO₂ layer 313a. Such a hybrid organic-inorganic two-phase system is in contrast with the totally inorganic two phase system of FIG. 1.

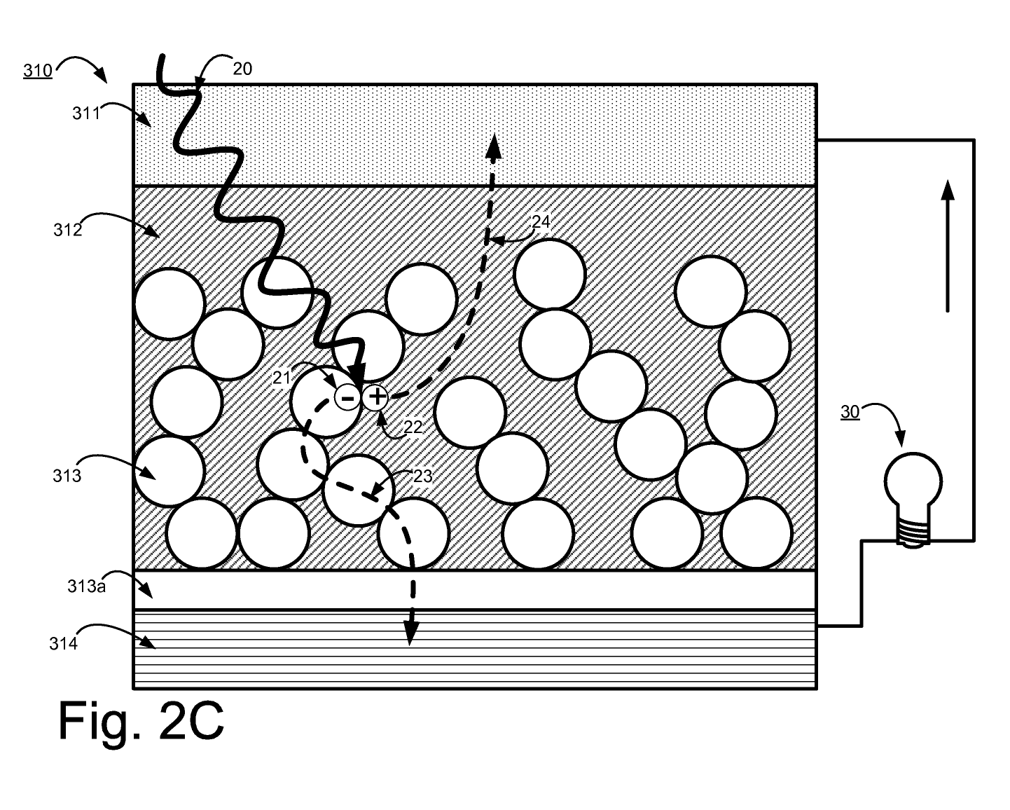

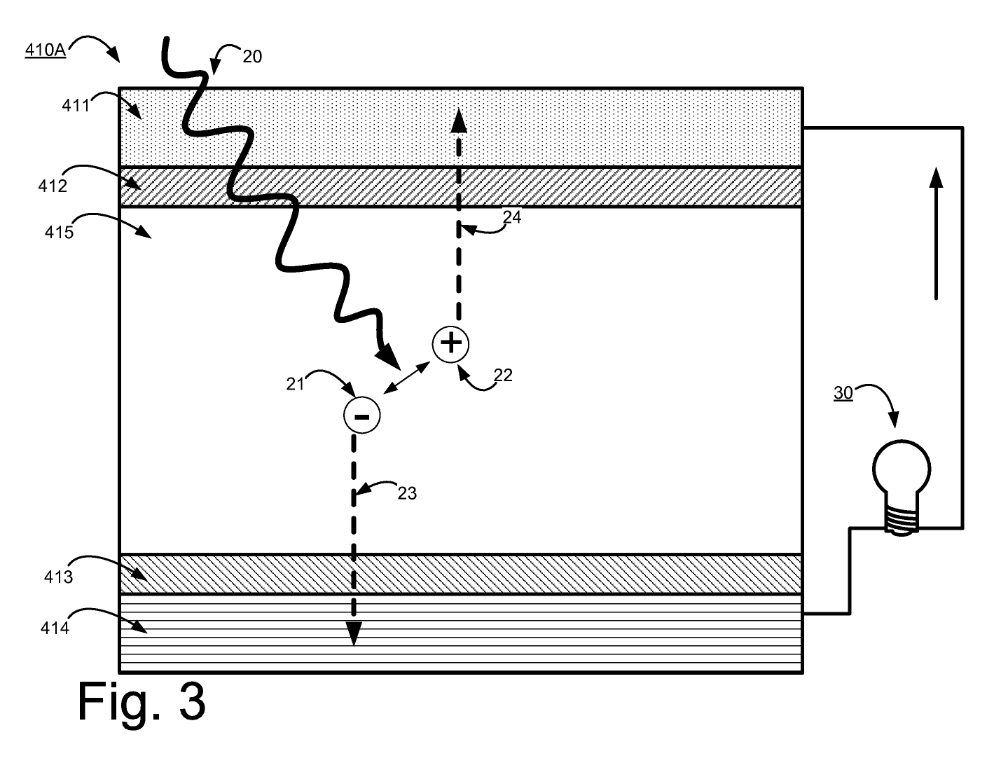

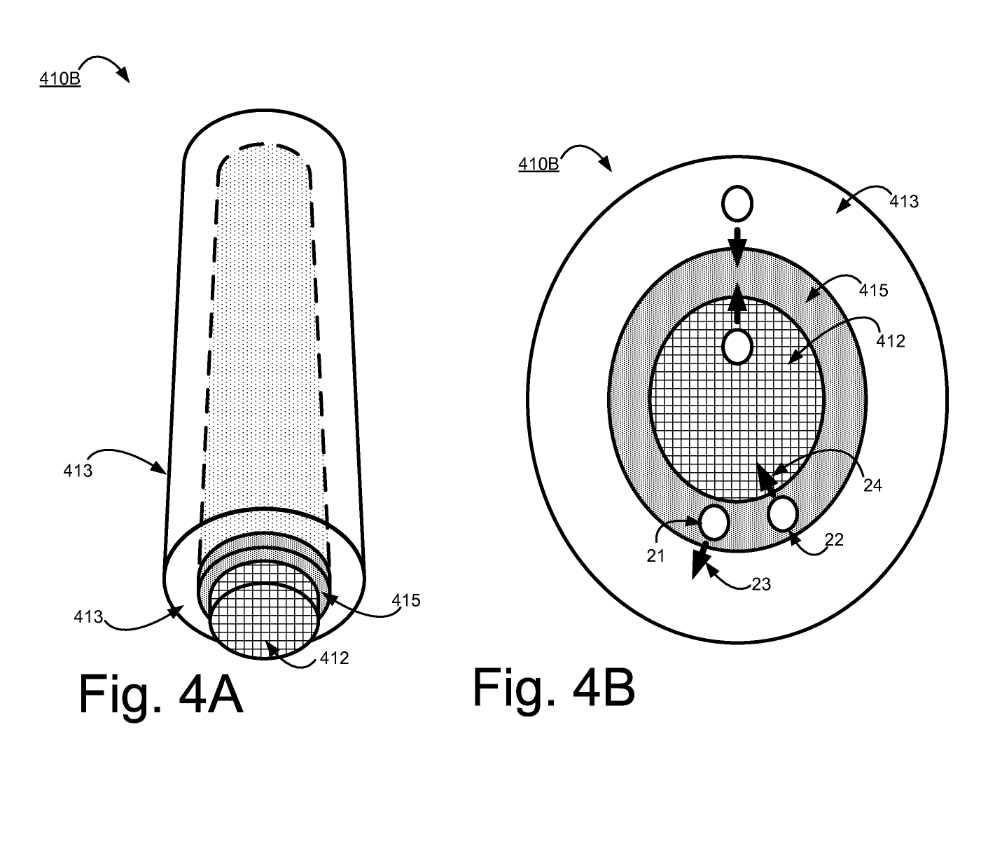

A further comparison can be made with the FIGS. 3 and 4 state of the art implementations. In FIG. 3, shown is a conventional non-nanostructured, p-i-n junction inorganic three-phase solar cell 410A. As a three-phase system, this configuration has an intrinsic (i) inorganic material 415 that acts as the light absorber and source of photogenerated electron-hole pairs. In comparison with FIG. 1, this system 410A is not a nanostructured system. As is further shown in FIG. 3, the (i) layer 415 is sandwiched between a p-type (p) inorganic material or layer 412 and an n-type (n) inorganic material or layer 413. In this arrangement, the (i) material absorbs the light and conducts both electrons 21 and holes 22. The (p) and (n) type phases collect/conduct holes and electrons, respectively via the conduction pathways 23 and 24. A TCO contact 411 and a Ti contact 414 are also shown here; noting that of these at least one is preferred to be transparent; however, the other may be either transparent or non-transparent, and may be any of many different materials not limited to Titanium. In a similar configuration, shown in FIGS. 4A and 4B is a nanowire p-i-n junction inorganic three-phase solar cell 410B. As with cell 410A of FIG. 3, and in contrast to the configuration of FIG. 1, this configuration 410B is defined by three-phases in which an intrinsic (i) inorganic material 415 absorbs light and generates electron-hole pairs (see electron 21 and hole 22 and corresponding conduction paths 23 and 24 in FIG. 4B). As shown in FIGS. 4A and 4B, layer (i) 415 conformally coats a p-type (p) inorganic nanowire 412, and an n-type (n) inorganic coating 413 forms a sheath around the p-i core-shell nanowire. In this arrangement, the (i) material is the source of photogenerated electron-hole pairs (i.e., absorbs light generates charges) and conductor of holes and electrons. The (p) and (n) type phases conduct only holes and electrons, respectively, and are not involved with light absorption.

Note, though other comparisons may also be made (as for example with non-nano-scaled wire models which may not provide anything near 1-D conduction pathways, and/or other electrolyte materials), these will not be addressed in detail any further herein.

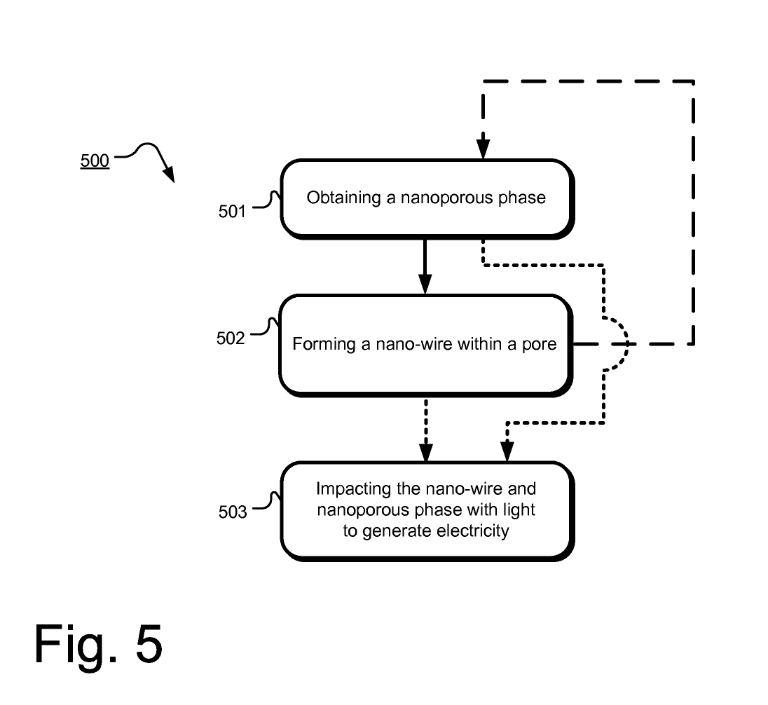

Exemplary nanowire composite products may be produced as follows. In one exemplary implementation, the nanowires may be grown under controlled conditions within the pores of the nanoporous structure. FIG. 5 provides a summary view of such a process, here process 500, in which a first step or operation 501 includes obtaining the nanoporous phase, the next step or operation 502 involving the formation of the nanowires filling multiple pores of the nanoporous phase. Note the additional, functional impacting of a light ray in contact with the nanoporous phase and/or nanowires for the operational generation of an electron-hole pair is shown as a step or operation 503 in FIG. 5 (as well as a functionality in each of FIGS. 1-4); however, the dotted line connection to operation 503 in FIG. 5 demonstrates the optionally discrete operability relative to the fabrication operations 501 and 502. Note, an alternative shown in dashed line in FIG. 5 may be available where operations 501 and 502 are reversed; i.e., it may be that one can do operation 502 before operation 501. Then, as the dotted line with jumper indicates, the operation 503 may be performed.

More particularly, in an exemplary fabrication method, a bottom-up electrochemical synthesis may be achieved of nanowires in a nanoporous structure, more particularly in this example, here, p-type semiconductors nanowires in oriented n-TiO₂ nanotube arrays as described further herein. Fabrication of adequately efficient semiconductor sensitized bulk heterojunction solar cells, i.e., the combination of the nanoporous phase and the nanowires disposed therein, includes the complete or substantially complete filling of the pore system of one semiconductor (host) material, typically here, the nanoporous phase, with nanoscale dimensions (<100 nm) with a different semiconductor (guest) material, here the nanowire array. Because of the small pore size and electrical conductivity of the host material, electrochemical approaches to fill the entire pore network can be difficult. Typically, during the electrochemical deposition process, the guest material blocks the pores of the host precluding complete pore filling. Described here is a general synthetic strategy for spatially controlling the growth of p-type semiconductors in the mesopores or nanopores of n-type metal oxide materials. As an illustration of this strategy, a facile electrochemical deposition of p-CuInSe₂ in nanoporous anatase n-TiO₂ oriented nanotube arrays and nanoparticle films is presented. By controlling the ambipolar diffusion length the p-type semiconductors can be deposited either as a pore-blocking overlayer (undesirable for the filling of the pore network until after the network has been filled) or from the bottom-up, resulting in substantially complete pore filling, as desired here.

Bulk semiconductor heterojunction cells are constructed of two interpenetrating charge-conducting networks—one for electrons and one for holes. One of the interpenetrating phases is typically a nanoporous semiconductor or phase, which serves as the host. The other is the guest material, which fills the pores of the host semiconductor. In a primary non-limiting example, here, the electron-conducting phase is a nanoporous (approx. 1-500 nm diameter pores) nanocrystalline metal oxide film, and the hole-conducting phase is an inorganic p-type semiconductor. Noting the difficulty in attaining complete pore filling and forming good electronic contact between the two charge-conducting networks, along with the nanoscale pore size (pores<500 nm), and the three-dimensional often disordered tortuous pore networks of conventional nanocrystalline TiO₂ films, electrochemical deposition has been found a facile and versatile technique for depositing semiconducting and conducting materials in nanoscaled pores. In general, here described is a general synthetic strategy for electrochemically controlling the spatial growth of p-type semiconductors in the nanopores of n-type metal oxide materials.

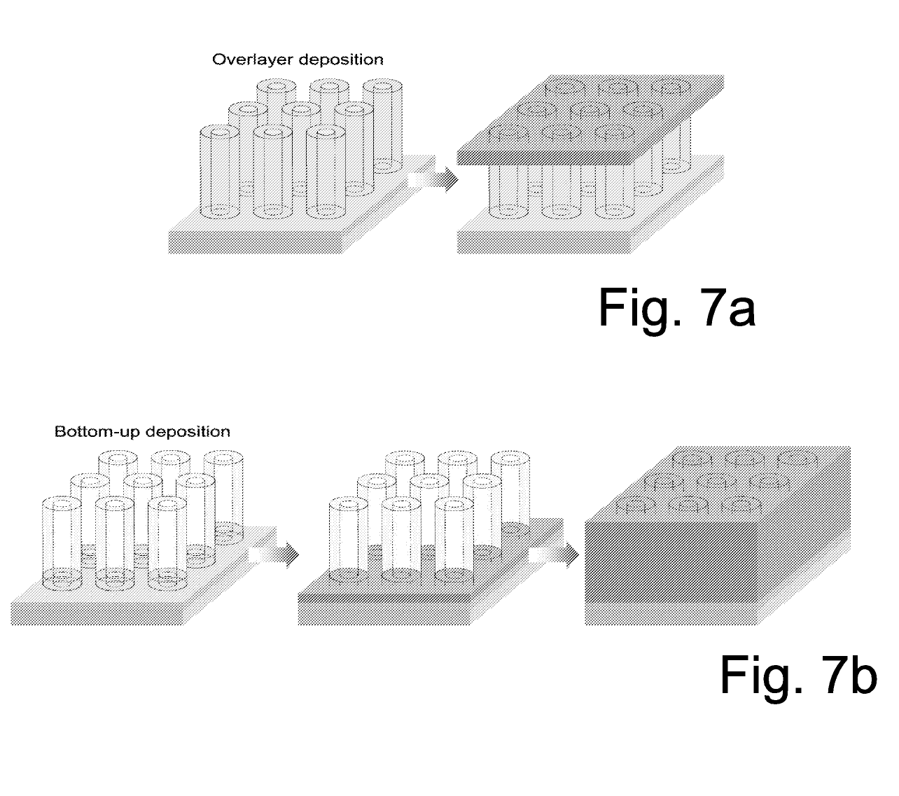

The strategy includes control of electrochemical deposition conditions (e.g., electron diffusion length and kinetics of interfacial charge transfer) for deposition of p-CuInSe₂ (CIS) nanoporous in anatase n-TiO₂ oriented nanotube arrays and nanoparticle films to semiconductor precursor species in the electrolyte. The average distance that electrons travel before they react with the precursor ions at the interface can be tuned—via the ambipolar diffusion effect—by varying the composition of the deposition solution to influence the spatial growth profile of the guest semiconductor in the pores of the host material. Changing the solution composition affects the ion electron diffusion coefficients and the interfacial electron transfer kinetics, which determines the effective electron diffusion length. By controlling the effective electron diffusion length (roughly 200-300 nm), the p-type semiconductors can be deposited either as a pore-blocking overlayer, see FIG. 7(a), or from the bottom-up (see e.g., FIG. 7(b), and also the filling between the walls 13(a), 13(b), 13(c) and 13(d) of FIG. 1, from the bottom going upward; bottom and upward merely being referential for ease in description, there being no limitation on orientation of the device implied thereby), resulting in pore filling of the pore network. This electrochemical approach may be used not only in the facile fabrications of heterojunction solar cells but also in other optoelectronic devices, inter alia.

### Example

In a specific example, a compact layer of TiO₂ was deposited on fluorine-doped SnO₂ conducting glass (TCO, TEC15) by spray pyrolysis. Cyclic voltammetry of ferrocene in acetonitrile-based electrolyte confirmed that the compact layer completely blocked access of ferrocene to the TCO substrate. Nanoporous TiO₂ nanoparticle films were then prepared by doctor blading a paste containing 25 nm-diameter anatase TiO₂ nanoparticles on the TCO covered with a TiO₂ compact layer. The films were calcined for 15 minutes at 500° C. in air. The average film was 4-8 μm thick with 28 nm pore diameters. The oriented titanium oxide nanotube arrays were prepared by electrochemically anodizing a Ti foil (Alfa, 0.25 mm, 99.5% purity) in a two-electrode cell, which contained a Pt counter electrode in 0.15 M ammonium fluoride in formamide with 3.5 wt % water; the composition of the solution was adapted from the literature. The Ti foil was biased at 20 V for 2 h at room temperature to produce 2 μm thick nanotube arrays. The average nanotube had a wall thickness of 12 nm and a pore diameter of 80 nm; the average intertube spacing was about 13 nm. The as-deposited nanotube films were then rinsed in ethanol and annealed at 400° C. in air for 1 h; annealing transforms the as-formed amorphous titanium oxide phase to the anatase TiO₂ phase.

Electrodeposition was carried out with a three-electrode cell with a Pt mesh counter electrode and a Ag/AgCl quasi reference (calibrated against [Fe(CN₆)]^{3-/4-}). A computer-controlled potentiostat (EG&G, PAR283) was used for the electrochemical deposition. The CuInSe₂ (CIS) deposition solutions contained 1 mM CuCl₂ (Aldrich, 97%), 5 mM H₂SeO₃ (Aldrich, 99.999%), and 30 mM InCl₃.4H₂O (Alfa, ultrapure) in ethanol (Pharmaco-Aaper, 200 prf), ethanol with 5 vol % water, or ethanol with 0.1 M TBACIO₄ (Fluka, puriss) unless otherwise stated. Typically, CIS deposition was conducted at constant potential for TiO₂ nanoparticle films and using potential pulse for TiO₂ nanotube (NT) films. For either CIS deposition mode, the potential was normally set at −0.95 V (vs. Ag/AgCl). Electrochemical impedance measurements were performed with a potentiostat (PAR283) equipped with a frequency response analyzer (Solartron, M1260) at a frequency range of about 0.1 to about 100 KHz and amplitude of 10 mV. The chemical capacitance of the electrodes was obtained by fitting the impedance spectra with Zview software (Scribner Inc.).

The crystalline structures of the annealed samples were characterized by X-ray diffraction (XRD) measurements with a Scintag XRD powder diffractometer (CuKα radiation (λ=1.540598 Å); 45 kV; 36 mA). Before conducting XRD measurements, the CIS samples were annealed in N₂ atmosphere at 350° C. for 2 h. The morphology of the nanoporous films was characterized by scanning electron microscopy (JEOL 7000F FESEM).

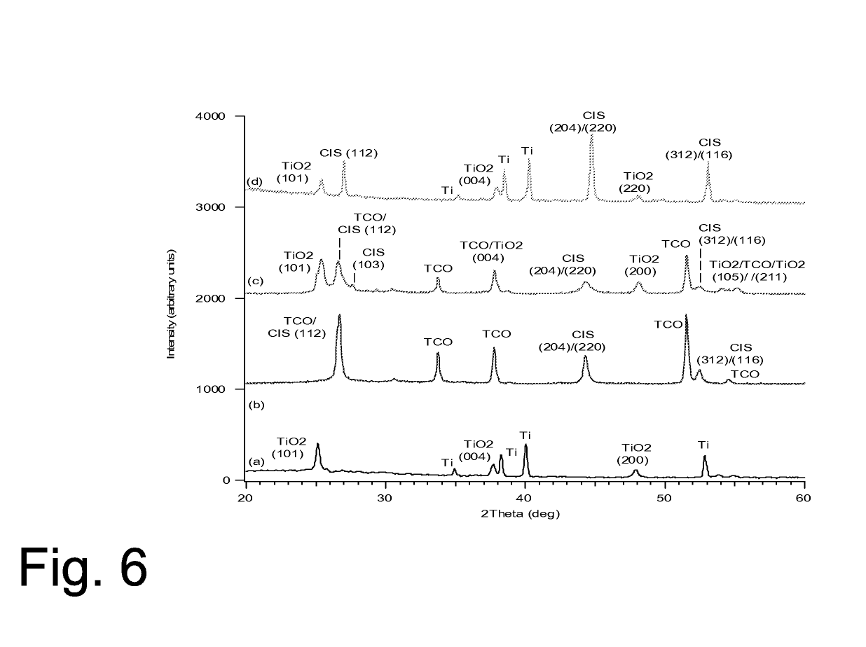

FIG. 6 displays X ray diffraction, XRD, patterns of (a) a TiO₂ NT film on Ti foil annealed at 400° C. in air for 1 h and annealed CIS films deposited (b) on TCO, (c) in a TiO₂ nanoparticle film on TCO, and (d) in a TiO₂ nanotube film on Ti foil. CIS-infiltrated films (b), (c) and (d) were annealed at 350° C. under N₂ for 2 h; the XRD spectrum for a CIS-free TiO₂ NT film (FIG. 6(a)) is shown as a reference. Fingerprint peaks in the XRD spectra for anatase TiO₂ and for tetragonal CuInSe₂ are evident. Compositional analyses of data from atomic emission spectroscopy measurements reveal that the annealed CIS films deposited on TCO (films were digested in nitric acid) showed a Cu/In/Se ratio of 1.11:0.89:1.85. The copper-rich nature of the film (Cu/In ratio of 1.2-1.3) is expected given the negative potential used for deposition. Such copper-rich films behave p-type. It is of note that when CIS is deposited in the nanoporous TiO₂ nanoparticle and NT films, the XRD peaks are shifted slightly and, in the case of the nanoparticle films, are broader than those for CIS deposited on bare TCO. These shifts may reflect a slightly different Cu:In stoichiometry or other distortion of the CIS crystal structure within the nanopores of the TiO₂ systems. Regardless of the exact Cu:In ratio, analyses of the data from energy dispersive X-ray spectroscopy (not shown) show that the CIS deposited in either TiO₂ nanostructure is copper-rich and, therefore, p-type.

This process is highly reproducible, and the morphology of the resulting product may be particularly advantageous for use as the active element in or directly as a solar cell. For example, electrochemical processing can be used to grow the nanowires or nanotubes directly on/in other porous materials as well to produce enhanced solar cell devices. Note, nanowire/nanotube forming reactions which are not necessarily electrochemical in nature may also be used, e.g., when nanowire growth can fill substantially the pores of the base material, bottom-up or otherwise.

In more specific terms, for preparing semiconductor nanowires of CuInSe₂ (CIS) in mesoscopic anatase n-TiO2 nanowire or nanotube arrays, a first quantity described as the effective electron diffusion length Lₙ can be used. As an initial point, when the electron diffusion length Lₙ is ≧the film thickness L (or the height of the walls 13(a), 13(b), 13(c) and the like in FIG. 1), deposition of the p-type semiconductor occurs preferentially near the ends of the opening of the nanotubes to produce a pore-blocking overlayer (see FIG. 7(a)); however, when Lₙ is <<L and is close to the conducting substrate, the growth of the p-type semiconductor begins near the bottom of nanotubes and progresses upwardly through the pore network (see FIG. 7(b)). The effective electron diffusion length Lₙ describes the statistical average distance that electrons travel from the conducting substrate to some region in the host film, e.g., the film or layer 13 in FIG. 1, before they react with redox (semiconductor precursor) species in an precursor electrolyte as described by the expression of equation (1) (Equation 1);

Lₙ=\sqrt{Dₙτᵣ} (1)

where Dₙ is the electron diffusion coefficient and τᵣ is the interfacial charge-transfer time constant, representing the reaction of electrons with the semiconductor redox precursor species or, simply, the electron lifetime. As understood from Equation 1, the effective electron diffusion length can be shortened by either reducing the electron diffusion coefficient Dₙ or decreasing the electron reaction time constant τᵣ.

The diffusion of electrons in the electrolyte-filled material is ambipolar, meaning that the mobile electrons in titania carry a cloud of countercharges (cations or holes) in the electrolyte. The electron and ion diffusion coefficients cannot, therefore, be determined separately. This is a well-known phenomenon in the diffusion theory of electrolyte solutions. The ambipolar diffusion coefficient D_{amb} can be described by the simplified mathematical expression (Equation 2)

$${D}_{amb} = \frac{n + p}{n / {D}_{p} + p / {D}_{n}} \qquad ( 2 )$$

where n and Dₙ are the electron density and diffusion coefficient, respectively, and p and Dₚ are the hole or cation density and diffusion coefficient in the electrolyte, respectively. It is apparent from Equation 2 that if the density of holes or cations p vastly exceeds the density of electrons n, D_{amb}=Dₙ. Conversely, if the electron density n significantly exceeds the cation density p, D_{amb}=Dₚ. The ambipolar diffusion length L_{amb} describes the statistical average distance that electrons travel from the conducting substrate to some region in the host film before they react with redox (semiconductor precursor) species in the electrolyte as described by the expression, Equation 3:

L_{amb}=\sqrt{D_{amb}τᵣ} (3)

where τᵣ is the interfacial electron-transfer time constant, representing the reaction of electrons with the semiconductor precursor ions or, simply, the electron lifetime. As can be seen by inspection, the ambipolar diffusion length can be shortened either by reducing the ambipolar diffusion coefficient D_{amb} or by decreasing the electron reaction time constant τᵣ.

Assuming a pseudo first-order reaction, the interfacial time constant for electron transfer from a surface energy level E to an oxidized redox species at a concentration cₒₓ is estimated from the expression (Equation 4):

$${τ}_{r} = \frac{A}{{c}_{ox}} \sqrt{\frac{πλ}{{k}_{B} T}} exp ( \frac{{E}_{redox} - E}{2 {k}_{B} T} ) \qquad ( 4 )$$

where A is a prefactor, λ is the reorganization energy, k_{B} is Boltzmann constant, T is temperature, and E_{redox} is the Fermi level of the redox couple in the electrolyte solution. It is evident that the electron reaction time constant τᵣ can be changed by adjusting cₒₓ(τᵣ∝1/cₒₓ), the oxidized redox species, at a given bias potential. Also, the solvent reorganization energy λ on electron lifetime may be considered, especially for the strongly solvating solvent. This influences the electron lifetime. For example, with increasing solvation energy, the deposition reaction is expected to become slower. For a further example, λ of Cu^{1+/2+} was estimated to be about 1 to about 1.5 eV in aqueous solution, where the large desolvation energy of the hydrated metal cations will slow the interfacial charge transfer process and result in a longer lifetime τᵣ. In contrast, the interfacial electron transfer rate involving a weakly solvating solvent is expected to be faster, as the disruption of solvated ions during interfacial charge transfer process is energetically more favorable (i.e., smaller λ).

Combining Equations 2, 3 and 4 yields an expression for the ambipolar diffusion length L_{amb}, Equation 5:

$${L}_{amb} = {( \frac{{A}^{2} πλ}{{k}_{B} T} )}^{1 / 4} {( \frac{1 + n / {c}_{ox}}{n / {D}_{p} + {c}_{ox} / {D}_{n}} )}^{1 / 2} exp ( \frac{{E}_{redox} - E}{4 {k}_{B} T} ) \qquad ( 5 )$$

where L_{amb} is expressed as a function of Dₙ, Dₚ, n and cₒₓ. In some of the cases in this study, cₒₓ is equivalent to the cation or hole concentration p in Equation 2. When the electron density n greatly exceeds the cation concentration in the electrolyte, the diffusion coefficient of cations Dₚ (≈D_{amb}) strongly influences L_{amb}, and when the cation density greatly exceeds the electron density, the diffusion coefficient of electrons Dₙ (≈D_{amb}) strongly affect L_{amb}. Also, because Dₚ is affected by the electrolyte properties, L_{amb} also depends on it. For example, the diffusion coefficients of ions are typically lower in organic electrolyte solutions than in aqueous electrolyte solutions, primarily owing to the size of the solvated ions (hydrodynamic radius) and the viscosity of the solutions.

FIG. 8 shows the dependence of the effective electron diffusion length L_{amb} (calculated using Equation 5) on the electrolyte concentration for both aqueous electrolyte (upper gray lines) and ethanol-based electrolyte (lower black lines). More particularly, FIG. 8 provides simulation curves for the dependence of the ambipolar diffusion coefficient (solid lines) and ambipolar diffusion length (dashed lines) on the concentration of the semiconductor precursors cₒₓ in solution. The simulation parameters are n=6.8×10²⁰ cm⁻³ and Dₙ=0.275 cm²/s at the deposition potential, −0.95 V (vs. Ag/AgCl), which is more negative than the TiO₂ conduction band potential. Black curves: Dₚ=10⁻⁶ cm²/s and τᵣ=10¹⁵/cₒₓ s for the cases where the CIS deposition solutions contain ethanol. Gray curves: Dₚ=10⁻⁵ cm²/s and τᵣ=10¹⁶/Cₒₓ for the cases in which the CIS deposition solutions contain ethanol with 5 vol % added water. The electron lifetime constants τᵣ were estimated from impedance measurements of nanoporous TiO₂ nanoparticle film infused with CIS deposition solutions containing 1 mM CuCl₂, 5 mM H₂SeO₃, and 30 mM InCl₃ in either aqueous or ethanolic electrolytes; e.g., ethanol or ethanol with 5 vol % added water. Pseudo first-order kinetics (τᵣ∝1/cₒₓ) are assumed. Simulations are based on Equation 5.

FIG. 8 shows the dependence of both the ambipolar diffusion length L_{amb} and the ambipolar diffusion coefficient Dₐₘₚ on the concentration of cationic precursor species cₒₓ in ethanolic electrolyte solutions. Impedance data (not shown) indicate that the interfacial electron lifetimes for films infused with absolute ethanolic deposition solutions were much shorter (ca. 1 ms at 10¹⁸ cm⁻³) than the ones with 5 vol % water (ca. 10 ms at 10¹⁸ cm⁻³). Correspondingly, from an examination of FIG. 8, the ambipolar diffusion lengths are predicted to be about 10 fold shorter in nanoporous TiO₂ films interpenetrated with absolute ethanolic deposition solutions than the ones with 5 vol % added water. At the lowest precursor ion concentration (cₒₓ=10¹⁷ cm⁻³) in FIG. 8, the electron density far exceeds the cation concentration in the electrolyte such that D_{amb}≈Dₚ (equation (2)). Under these conditions, the sluggish motion of cations retards the motion of electrons causing D_{amb} to decrease considerably, by about a factor of 10³, compared with the situation, where cₒₓ is at its highest value (10²⁴ cm⁻³) in FIG. 8 and D_{amb}≈Dₙ. As the cₒₓ declines, the interfacial electron reaction time constant increases (Equation 4), resulting in an increase of L_{amb} (FIG. 8). Conversely, as the cₒₓ increases, τᵣ decreases, leading a decrease of L_{amb} (FIG. 8). These simulations imply that the ambipolar diffusion length can be altered by varying the solution composition. Such variations allow control of the spatial location for the deposition of p-type semiconductors in electrolyte-infused nanoporous nanostructured films. These results teach that it is feasible to construct sensitized bulk heterojunctions by bottom-up electrochemical synthesis.

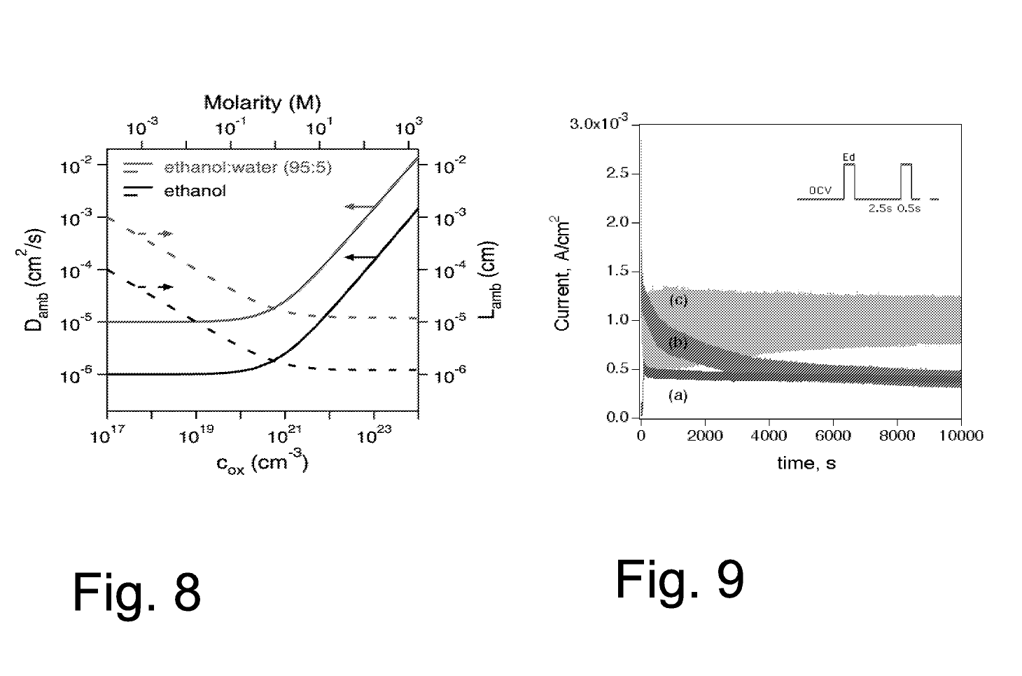

FIG. 9 shows the current profile of pulse electrodeposition or potential pulse deposition of CIS in TiO₂ nanotube electrode arrays using (a) 1 mM CuCl₂/5 mM H₂SeO₃ and 30 mM InCl₃ in ethanol, or (b) ethanol with 5 vol. % H₂O; or (c) with ethanol with 0.1M TBAClO₄. The apparent current density is calculated from projected area. The pulse or deposition potential was −0.95V (vs. Ag/AgCl), being above the conduction band edge of TiO₂. The curve of FIG. 9(a) (ethanol alone) demonstrates a deposition current drops gradually at the beginning and then keeps almost constant, indicating a kinetic transition from a reaction controlled to a mass transport controlled process. It is noted that the deposition starts at the bottom until the potential is more negative than about −1.15V, whereas the deposition occurs on the top surface of the film in aqueous electrolyte even when the potential is as positive as −0.25V. The curve of FIG. 9(b) (ethanol with 5 vol % added water) demonstrates a relatively long, gradual decay before becoming almost constant. FIG. 8 teaches that adding water increases the ambipolar diffusion length, though it appears that the initial current decay may be associated with the formation of a thin layer of CIS on the walls of the nanotubes; followed by mass transport controlled process like that for the ethanol alone example of FIG. 9(a). Curve 9(c) shows that when the deposition solution contained ethanol with 0.1 M TBAClO₄, the current displays, when compared with curve 9(b), a relatively short initial decay before reaching steady state. Because adding a supporting electrolyte (0.1 M TBAClO₄) increases the ambipolar diffusion coefficient (Equation 2) and, therefore, increases the ambipolar diffusion length (FIG. 8), the deposition mechanisms governing curves 9(b) and 9(c) are almost the same. However, adding the extra electrolyte is not expected to affect the electron reaction time constant (Equation 4). Both the measured electron reaction time constant and the ion diffusion coefficient (FIG. 8) for the deposition solution containing ethanol are smaller than the ones for the deposition solution made up of ethanol with 5 vol % added water. The implication of these measurements is that the transition from the rate-limiting reaction of electrons to mass-transport-controlled process may be faster in ethanol with 0.1 M TBAClO₄ than in ethanol with 5 vol % water. The faster transition may lead to a more rapid buildup of a pore-blocking layer, which limits the amount of CIS deposited on the nanotube walls within the nanopores. This conclusion is consistent with the SEM images described below which suggests that CIS layer coating the nanotube walls are thinner—as reflected by the larger unfilled intertube spacing—when the deposition solution contains ethanol with extra supporting electrolyte than when it made up of ethanol with 5 vol % water and no extra electrolyte. The results of FIG. 9 and the SEM depictions set forth below suggest that the spatial growth profile of CIS in the nanopores of TiO₂ films can be controlled by judiciously changing the electrochemical conditions (the composition/concentration of the deposition solution, electrode potential, etc.). In this way, the mechanism for deposition can be changed from a reaction in which transport controls interfacial charge transfer to one that is mass transport-limited.

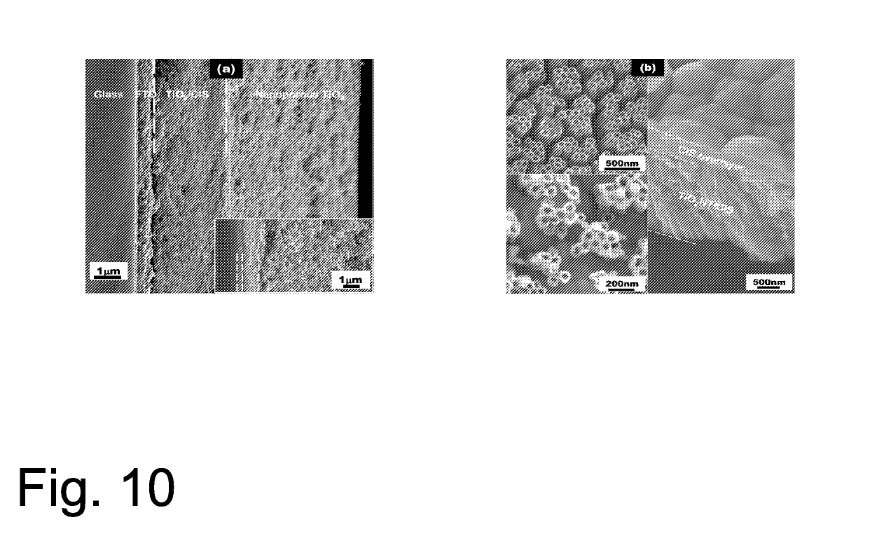

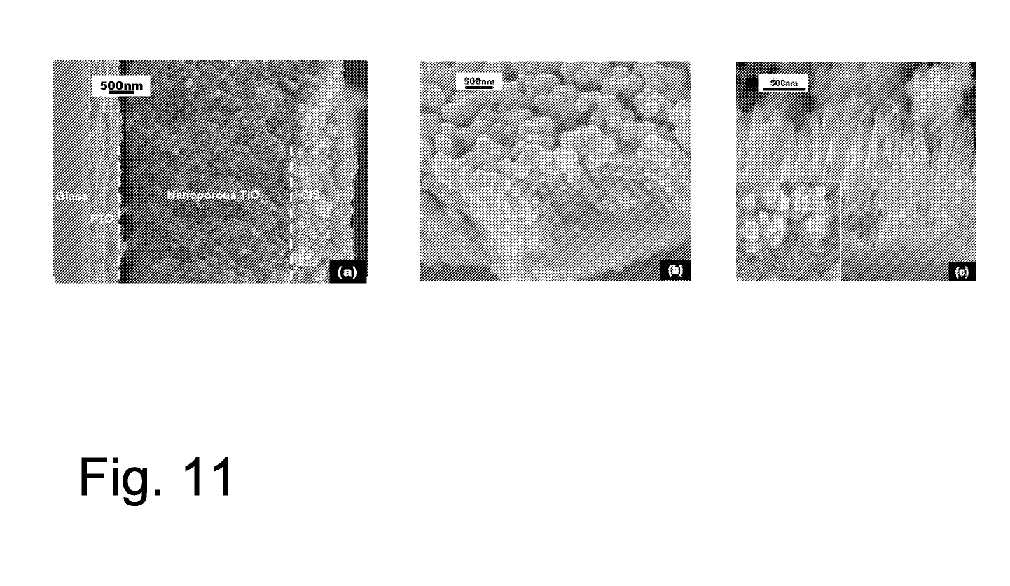

FIGS. 10 and 11 provide Scanning Electron Microscopy images of CIS electrodeposited in nanoporous TiO₂ nanoparticle and oriented nanotube films. FIG. 10(a) shows the cross-sectional SEM image of the morphology of deposited CIS in mesoscopic TiO₂ particle film when the deposition solution contained ethanol. The part of the film close to the FTO substrate became much denser after CIS deposition; in contrast, the top portion of the TiO₂ film remains unchanged. The inset of FIG. 10(a) shows the cross-sectional SEM image of a similar sample but with much shorter deposition time. The deposition of CIS starts from the bottom near the electrode/substrate interface. The same growth phenomenon is also seen for TiO₂ nanotube arrays. FIG. 10(b) shows SEM images of TiO₂ nanotubes filled with CIS that has been deposited over a period of from about 0 to between about 6 and 8 hours. In comparison to the original nanotube arrays (the upper left inset image in FIG. 10(b)), the nanotubes after about 6-hour growth of CIS (lower left inset) have the most part of the nanotubes filled with CIS. FIG. 10b also shows a SEM image of TiO₂ nanotubes filled with CIS that has been deposited for 8 hours (right side view of FIG. 10(b)). In contrast with the earlier views of FIG. 10(b), the entire TiO₂ nanotubes were ultimately buried with a continuous overlayer of CIS formed on the top (right hand view of FIG. 10(b)).

FIGS. 11(a), 11(b) and 11(c) show SEM images of CIS deposition in TiO₂ films using electrolyte with 5 vol % H₂O. In contrast to the ethanolic electrolyte (FIG. 10), the presence of water in the electrolyte induces the deposition of CIS on top of the nanoporous TiO₂ film and thus, there is very little deposition of CIS deep inside the porous layer of the nanoparticle film. The addition of water is expected to enhance the dissociation of salts, and consequently, to increase the amount of free charges in the electrolyte. Also, the interfacial charge transfer time constants are likely to increase with the presence of water (FIG. 8), resulting from strong solvation between water molecule and ion species. So the effective electron diffusion length is expected to increase significantly, facilitating the deposition on the top surface of electrode. These SEM images (FIG. 11(a) and (b)) are therefore consistent with a long ambipolar diffusion length (FIG. 8), which foster a more rapid buildup of a CIS layer near the pore entrance at the outermost surface of the films than in the interior of the pore network. FIG. 11(c) shows SEM images of CIS deposition in TiO₂ nanotube films using electrolyte containing 0.1 M tetrabutylammonium perchlorate (TBAClO₄) supporting salts (electrochemical inert during electrodeposition of CIS). From this, CIS can be seen as mainly deposited on the tops of TiO₂ nanotubes and eventually formed a continuous overlayer. The addition of supporting electrolyte may enhance the electron diffusion coefficient (Equation 2) without affecting the interfacial charge transfer time constants, and therefore, may increase the effective electron diffusion length (Equation 3), leading to the growth of CIS on the top of TiO₂ films. In both cases, the deposition of a CIS overlayer on the top of the TiO₂ films during the initial deposition stage will eventually block the growth of materials inside the nanopores/nanotubes of TiO₂ films.

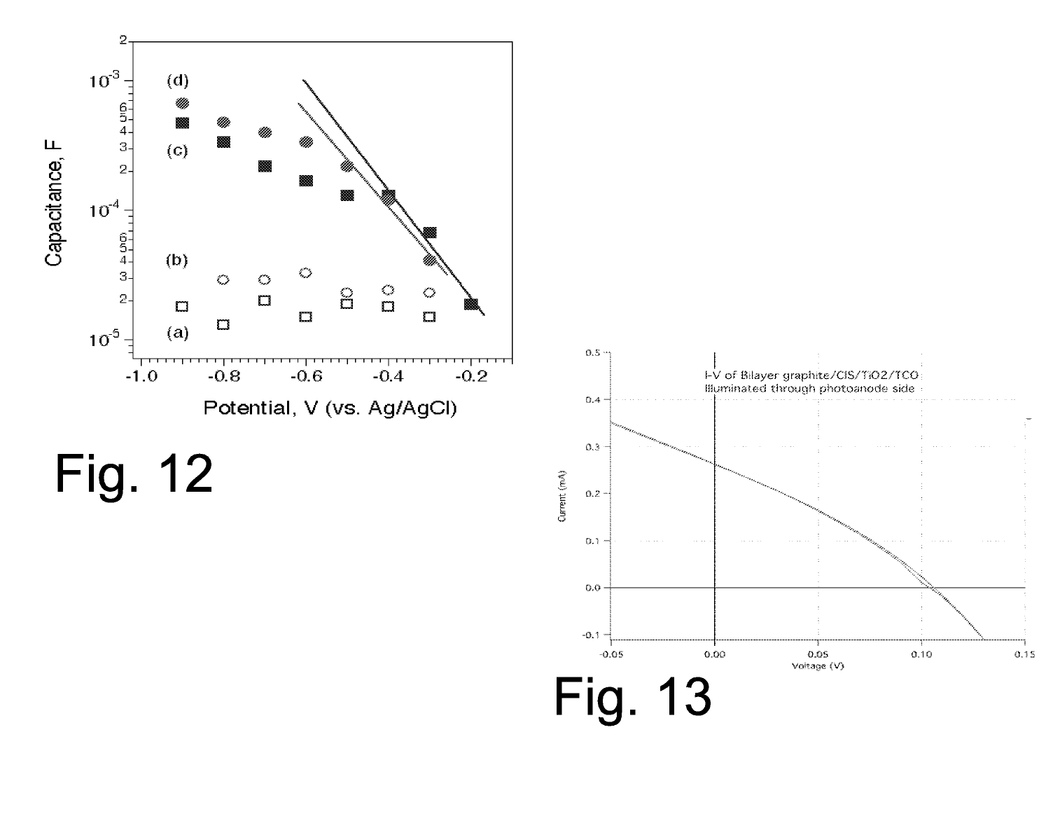

As the chemical capacitance (C_{μ}) of the electrode is proportional to the area addressable to electrons, e.g., substantially linearly proportional to the internal surface area of a TiO₂ nanotube array, C_{μ} is introduced here as an indicative parameter to evaluate the effects of electrolyte on the effective electron diffusion length. FIG. 12 shows the chemical capacitance of mesoscopic TiO₂ nanoparticle film in various electrolytes; namely, solutions containing 12(a) 10 mM CuCl₂ in ethanol (represented by hollow squares), 12(b) 10 mM H₂SeO₃ in ethanol (hollow circles), 12(c) 10 mM CuCl₂ in ethanol with 5 vol % water (solid squares), and 12(d) 10 mM H₂SeO₃ and 0.1 M TBAClO₄ in ethanol (solid circles). When the TiO₂ electrode was immersed either in the electrolyte consisted of 10 mM CuCl₂ dissolved in the mixture of ethanol and 5 vol. % water (FIG. 12(c)) or in the electrolyte containing 10 mM H₂SeO₃ and 0.1 M TBAClO₄ dissolved in ethanol (FIG. 12(d)), the values of C_{μ} is characterized by an exponential dependence at low biases, which is in accordance with the exponential distribution of the localized states in the band gap of TiO₂. However, as the bias potential increases (negatively), the values of C_{μ} deviate to lower values than predicted by the exponential dependence. This deviation is likely caused by the precipitate of reduced products on the TiO₂ surface and/or the limitation of double layer capacitance at higher bias potential. In contrast, when the TiO₂ electrode was immersed in the electrolyte consisted of 10 mM CuCl₂ (FIG. 12(a)) or H₂SeO₃ (FIG. 12(b)) dissolved in ethanol, the values of C_{μ} are almost independent of bias potential and are significantly smaller than those in electrolytes containing either water or TBAClO₄. This anomalous phenomenon can be understood as follows: at extremely low bias potential, the electron density is much less than the ion concentration/hole density (i.e., n<<p) and the whole film is addressable to electron transport. With increasing bias potential, in addition to the possible influence from precipitates and double layer capacitance (see above), n becomes comparable to or larger than p, and consequently, electron transport in TiO₂ is expected to be dominated by the sluggish motion of ion clouds in the electrolyte. Inasmuch as the interfacial charge transfer rate still increases exponentially with the bias potential, the effective electron diffusion length in TiO₂ is expected be shortened. Considering the collective effect of all these factors, the change of the total chemical capacitance in ethanolic electrolyte is expected to have little dependence on the bias potential. FIG. 12 shows that the values of C_{μ} using ethanolic electrolytes are about 30 times less than those using electrolytes containing either water or TBAClO₄, when the bias potential is fixed at −0.95V (the relevant potential used for electrodeposition). Assuming the entire TiO₂ electrode is electrochemically addressable to electrons using electrolytes containing either water or TBAClO₄, the electron addressable length (or Lₙ) in TiO₂ film may be about 30 times less in ethanolic electrolyte, being about 270 nm considering the film thickness of about 8 μm. Hence, the interfacial charge transfer reaction is constrained within a narrow region close to the electrode/substrate interface, in agreement with the SEM results (FIGS. 10 and 11). The significant difference in the film thickness addressable to electrons for electrodeposition using different electrolyte also suggested that, in contrast to the apparent current density per projected film area (t=0 s) displayed in FIG. 9, the actual current density per internal surface area available to deposition reaction in ethanolic electrolyte (FIG. 9(a)) is actually much higher than that with electrolytes containing 5 vol. % water (FIG. 9(b)), concurring that the interfacial charge transfer rates in ethanolic electrolyte are indeed much faster than that in water-containing electrolyte. In contrast, the inert solute TBAClO₄ has much less effect on the interfacial charge transfer rates (FIG. 9(c)).

In summary, profile-controlled electrochemical growth of various p-SC in the nano-matrix of anatase TiO₂ electrode (consisting of either nanoparticles or nanotubes) was successfully presented. It shows that the electrolyte property plays a role in mediating the effective electron diffusion length for spatially-controlled growth of p-SC in mesoscopic TiO₂ film. The preparation of bulk heterojunction by profile-controlled electrodeposition technique is expected to extend beyond anatase TiO₂ to a wide realm of mesoscopic semiconducting electrodes, enabling facile fabrication of novel nanostructured photovoltaic devices.

Photovoltaic results of an exemplary non-nano-structured bilayer two-phase CIS-TiO₂ device are shown in FIG. 13. In particular, a bilayer CIS-TiO₂ device was constructed of a thin, nonporous TiO₂ layer on a transparent conducting oxide (TCO) substrate, which shows a measurable photoelectric effect. With this bilayer structure, illumination occurs through the side of the cell opposite to the CIS overlayer, and the CIS that absorbs the light is in intimate contact with TiO₂. The TiO₂ layer is coated with a thin, nonporous CIS layer electrodeposited via substantially the same conditions used to fill the TiO₂ nanotubes. Because the contact to CIS may be other than transparent, graphite was used for this purpose. The results of an I-V (current-voltage) measurement with this device are shown in FIG. 13. In particular, shown is an I-V curve of a layered graphite/CIS/TiO₂/TCO device. Specifically, J_{sc}=0.26 mA cm⁻²; FF=0.31; V_{oc}=0.105 V; η=0.008%. The unmasked cell area was 0.22 cm². Although the photovoltaic (PV) properties are not extreme, an interpenetrated two-phase nanostructured architecture, such as that with nano-wires/nanotubes as described herein using these two materials may be expected to exhibit sufficient performance characteristics.

Regarding FIG. 14, which includes sub-part 14A and 14B, the gray image in FIG. 14A is the nanowire mesh (CdSe) or CdSe inverse opal. From this it can be seen that the pores between the 3D branched nanowires are empty. It may also be seen that there is a lot of order to this system, i.e., non-random disposition of materials, even though the wires are not oriented in a certain 2D direction, as for example the substantially vertical orientation shown in FIG. 1. In exemplary embodiments, the empty space may be filled with a second semiconductor/charge conducting phase. In one implementation, polystyrene or the like can have first been formed in an orderly array, with the Cadmium Selenide (CdSe) then filling the pores to generate the array shown in FIG. 14, both 14A and 14B. The polystyrene may then have been removed, and a second semiconductor interpenetrated in the interstitial areas between the NW mesh shown to form the substantially non-oriented but nonetheless ordered 3D cell structure. FIG. 14B displays a 2D cross-sectional slice of FIG. 14A, in which the path an electron 25 (or hole 26) may take through the CdSe inverse opal or semiconductor charge-conducting phase may provide a continuous, directional pathway (owing to the architectural order) for charge transport.

While a number of exemplary aspects and implementations have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

1. An inorganic two-phase nanowire structure with at least one ordered phase comprising:
an inorganic semiconducting nanoporous charge conducting phase; and,
an inorganic semiconductor nanowire array interpenetrated within the nanoporous charge conducting phase.

2. A sensitized solar cell including the inorganic two-phase nanowire structure of claim 1.

3. The inorganic two-phase nanowire structure of claim 1 wherein the inorganic semiconducting nanoporous charge conducting phase is one or both of ordered and orientationally ordered.

4. The inorganic two-phase nanowire structure of claim 1, wherein the inorganic semiconducting nanoporous charge conducting phase is one or more of an inorganic oxide, a metal oxide, a non-organic charge-conducting material capable of one or both of electron or hole conduction, and one or both of semitransparent or transparent to sensitizer-absorbed wavelengths of light.

5. The inorganic two-phase nanowire structure of claim 1, wherein the inorganic semiconducting nanoporous charge conducting phase is one or more of a wide-bandgap semiconducting oxide, an n-type material, TiO₂, ZnO, SnO₂, a p-type material, CuSCN, CuI, GaN, or NiO.

6. The inorganic two-phase nanowire structure of claim 1, wherein the inorganic semiconducting nanoporous charge conducting phase has a pore structure and the pore structure serves as a template to control the diameter, length, shape, orientation, and density of the nanowire array.

7. The inorganic two-phase nanowire structure of claim 1, wherein the inorganic semiconductor nanowire array is one or both of a sensitizer and a conducting phase.

8. The inorganic two-phase nanowire structure of claim 1, wherein the inorganic semiconductor nanowire array is one or both of:
a sensitizer, light absorber and source of photoinjected charge electrons or holes; and,
a conductor of one of holes or electrons.

9. The inorganic two-phase nanowire structure of claim 1, wherein the inorganic semiconducting nanowire array is one or more of quantum and/or non-quantum, narrow-bandgap, a p-type semiconductor, an n-type semiconductor, CuO, CdTe, and CdSe, CuInSe₂, CuSCN and, Si.

10. The inorganic two-phase nanowire structure of claim 1, wherein the inorganic nanowires are formed using an electrochemical process controlling the effective electron diffusion length.

11. The inorganic two-phase nanowire structure of claim 1 adapted for use as a solar cell.

12. The inorganic two-phase nanowire structure of claim 1, wherein the inorganic nanowires are formed using an electrochemical process including:
providing a nanoporous phase and an inorganic precursor material for the formation of nanowires;
growing the nano-wires in the pores of the nanoporous phase to produce a two-phase nanowire structure; and
incorporating the two-phase nanowire structure as an active element as a sensitized solar cell.

13. A method for producing an inorganic two-phase nanowire structure, comprising:
providing a nanoporous phase and an inorganic precursor material for the formation of nanowires; and,
electrochemically producing an inorganic two-phase nanowire structure by controlling the effective electron diffusion length.

14. The method of claim 13 wherein the producing of an inorganic nanowire structure is bottom-up.

15. The method of claim 13, further including:
incorporating the inorganic two-phase nanowire structure as an active element as a sensitized solar cell.

16. The method of claim 13, wherein the nanoporous phase is one or more of a charge-conducting material capable of one or both of electron or hole conduction and one or both of semitransparent or transparent to sensitizer-absorbed wavelengths of light; a non-metal oxide, a metal oxide, a wide-bandgap semiconducting oxide, a p-type material, an n-type material, TiO₂, ZnO, SnO₂, CuSCN, CuI, GaN, Ge, Se, Si or NiO.

17. The method of claim 13, wherein the nanoporous phase has a pore structure and the pore structure serves as a template to control the diameter, length, shape, orientation, and density of the nanowires.

18. The method of claim 13, wherein the inorganic nanowires are one or more of: a sensitizer, light absorber and source of photoinjected charge electrons or holes, a conductor of one of holes or electrons, quantum and/or non-quantum, narrow-bandgap, a p-type semiconductor, CuO, CdTe, and CdSe, CuInSe₂, CuSCN and an n-type semiconductor, or Si.

19. A nanowire composite sensitized solar cell produced according to the process of claim 13.

20. A method for production of a nanowire structure comprising:
forming a nanowire array without a corresponding conducting phase, and,
filling the spaces in the nanowire array with a corresponding conducting phase;
wherein the these operations may be performed either in this order or in reverse order.
